(19) United States
(12) Patent Application Publication
(10) Pub. No.: US 2006/0163668 A1
(43) Pub. Date: Jul. 27, 2006

(54) Semiconductor device and method for manufacturing same

(75) Inventor: Tomoko Matsuda, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/336,767

(22) Filed: Jan. 23, 2006

(30) Foreign Application Priority Data
Jan. 24, 2005 (JP) 2005-015289

(51) Int. Cl. H01L 29/76

(52) U.S. Cl. 257/382

(57) ABSTRACT

In the method for manufacturing the semiconductor device including a salicide film, prior to the process for forming the salicide film (S30), the operation for protecting the oxide film is conducted in order to prevent the scattering of the oxide film on silicon substrate (S10). Then, the operation for cleaning the surface of the silicon substrate is conducted via a dry etch (S20). Thereafter, the salicide film is formed (S30). Thereby reliability of the semiconductor device including the salicide film is enhanced.

This application is based on Japanese Patent Application No. 2005-15289, the content of which is incorporated hereinto by reference.

### BACKGROUND

1. Technical Field

The present invention relates to a semiconductor device and a method for manufacturing thereof.

2. Related Art

In recent years, a technology for forming a salicide metal layer on a surface of a semiconductor device, for the purpose of achieving a reduced resistance of a polysilicon interconnect and a diffusion layer in the semiconductor device, is known. Before the formation of the salicide metal layer, an operation for conducting a cleaning process with a diluted HF or the like is employed to remove a native oxide film and/or contaminants formed on the surface of the semiconductor substrate and/or a surface of a gate electrode. However, when a buried device isolation region composed of a silicon oxide film is formed in the semiconductor substrate, a silicon oxide film is dissolved into diluted HF and corners of the device isolation region are also dissolved, and thus a problem of a precipitation of water glass on the surface of the device isolation region is caused.

Japanese Laid-Open Patent Application No. 2004-55,791 discloses a technology for cleaning such semiconductor device with diluted HF while covering the front surface of the buried insulating film formed in the semiconductor substrate with a protective film of a material having a resistance to diluted HF. It is described that a fear for dissolving the buried insulating film into diluted HF can be avoided, since the buried insulating film is covered with the protective film during such cleaning process. Then, a salicide metal layer is formed.

However, in order to conduct a wet etching with diluted HF in the cleaning process like the conventional technology, it is necessary to once unload the semiconductor substrate from the deposition apparatus to transfer thereof to a wet processing apparatus. Therefore, a native oxide film may be formed on the semiconductor substrate during the unloading procedure, so that it is difficult to provide a sufficient cleaning.

### SUMMARY OF THE INVENTION

According to the present invention, there is provided a method for manufacturing a semiconductor device, including: forming a concave portion for forming a device isolation region in a silicon substrate; filling the concave portion with an insulating film containing a first silicon nitride film to form the device isolation region, the first silicon nitride film being formed on a side wall of the concave portion; forming a semiconductor element in a region isolated by the device isolation region on the silicon substrate, the semiconductor element including a gate electrode having a side wall formed at a side surface thereof; etching the entire surface of the silicon substrate by a dry etching process; and forming a salicide film on the silicon substrate after the dry etching process.

According to the present invention, there is provided a semiconductor device, including: a silicon substrate; a device isolation region filled with an insulating film, the insulating film including a first silicon nitride film formed at a side wall of a concave portion that is formed in the silicon substrate; a semiconductor element including a gate electrode that has a side wall formed at a side surface thereof, the semiconductor element being formed in a region on the silicon substrate that is isolated by the device isolation region; and a salicide film formed on the silicon substrate, wherein an upper portion of the insulating film is formed to be substantially even.

When the device isolation region is composed of the silicon oxide film, a cleaning process conducted via a dry etch process may cause a problem, in which the silicon oxide film is scattered during the cleaning process, being adhered onto the silicon substrate. According to the method for manufacturing the semiconductor device of the present invention, the silicon nitride film is formed on at least the side wall of the device isolation region, so that the scattering of the oxide can be reduced, thereby providing a prevention to the adhesion of the oxide onto the surface of the silicon substrate. Consequently, sufficient cleaning can be achieved only by the dry etch process, without a need for conducting a wet etch process with diluted HF in the cleaning process. This can provide a removal of the native oxide film and the contaminants without the need for unloading the semiconductor substrate from the deposition apparatus in the cleaning process, such that regeneration of a native oxide film after the cleaning can be prevented, thereby providing a manufacture of the semiconductor device having an improved reliability.

Here, the dry etch process may utilize an radio frequency (RF) plasma process employing an inert gas such as nitrogen gas, argon gas and the like. In addition, the gas available in this process may be a reducing gas such as hydrogen gas.

Japanese Patent Laid-Open No. 2004-55,791 describes an exemplary implementation that employs a silicon nitride film for a protective film covering the front surface of the buried insulating film (device isolation region). The scattering of the oxide can also be reduced in the dry etch process by covering the side of the surface of the buried insulating film with the silicon nitride film, and thus it is expected that the adhesion of the oxide onto the surface of the silicon substrate is prevented. Nevertheless, such protective film must be formed via a lithographic technology that employs a photo resist, resulting in an increased number of the processes required for manufacturing the semiconductor device. In addition, since it is necessary to cover the entire surface of the buried insulating film formed in the silicon substrate with the protective film, it is required to form slightly larger protective film than the surface area of the buried insulating film, taking into consideration of an alignment difference in an aligning process, leading to a problem of increasing the total area of the semiconductor device.

According to the present invention, sufficient cleaning can be achieved only via the dry etch process, while inhibiting the scattering of the silicon oxide film in the dry etch process with a simple manufacturing process.

For the salicide film, silicide compounds of various metals that are known as capable of being silicidized, such as cobalt (Co), nickel (Ni), titanium (Ti), iron (Fe), palladium (Pd), platinum (Pt) and the like, may be employed. The present invention is particularly useful, when a mono silicide such as nickel silicide (NiSi) is formed, among these compounds. The reason will be described as follows.

When NiSi is to be formed as the salicide film, the oxide accumulated on the surface of the silicon substrate easily promotes a creation of disilicide. If the silicon oxide film is exposed on the surface thereof in the dry etch process conducted as a pre-processing for the salicidation process, silicon oxide from the silicon oxide film is scattered over the surface of the silicon substrate, thereby promoting a formation of disilicide. Disilicide may cause a leakage in the diffusion layer. Therefore, in order to create mono silicide such as NiSi, the removal of the oxide film should be conducted more carefully than the case of forming other type of silicide film. As described above, since the silicon nitride film is formed on the side wall of the device isolation region according to the present invention, scattering of the oxide can be reduced, resulting in preventing the adhesion of the oxide onto the surface of the silicon substrate. This allows a preferential formation of mono silicide.

Further, the investigations conducted by the present inventor clarify that the tensile stress created in the silicon substrate viewing from the film formed on the upper layer of the silicon substrate is increased by forming a liner of silicon nitride film on the side wall of the device isolation region, as compared with a case of forming the device isolation region only with a silicon oxide film. This also promotes the formation of mono silicide.

On the other hand, it has been clarified by the present inventor that the tensile stress created in the silicon substrate viewed from the film formed on the upper layer of the silicon substrate is decreased by composing the device isolation region of a silicon oxide film and coating the surface thereof with a silicon nitride film (such structure is described in Japanese Patent Laid-Open No. 2004-55,791), as compared with a case of having no silicon nitride film for coating. This promotes the creation of disilicide. Therefore, from this point of view, it is preferable to form a liner of a silicon nitride film on the side wall of the device isolation region, in order to create mono silicide such as NiSi.

According to the present invention, the reliability of the semiconductor device including the salicide film can be enhanced.

### BRIEF DESCRIPTION OF THE DRAWINGS

The above and other objects, advantages and features of the present invention will be more apparent from the following descriptions taken in conjunction with the accompanying drawings, in which:

FIG. 1 is a flow chart, showing a process for manufacturing a semiconductor device in an embodiment of the present invention;

FIGS. 2A to 2C are cross-sectional views, illustrating a process for manufacturing the semiconductor device in the embodiment of the present invention;

FIGS. 3A to 3C are cross-sectional views, illustrating a process for manufacturing the semiconductor device in the embodiment of the present invention;

FIGS. 4A and 4B are cross-sectional views, illustrating a process for manufacturing the semiconductor device in the embodiment of the present invention;

FIGS. 5A to 5C are cross-sectional views, illustrating a process for manufacturing the semiconductor device in another embodiment of the present invention;

FIG. 6 is a cross-sectional view, illustrating a process for manufacturing the semiconductor device in the embodiment of the present invention; and

FIGS. 7A and 7B are cross-sectional view, illustrating other examples of the side wall example of the semiconductor device of the present invention.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Preferable embodiments according to the present invention will be described as follows in further detail, in reference to the annexed figures. In all figures, an identical numeral is assigned to an element commonly appeared in the figures, and the detailed description thereof will not be repeatedly presented.

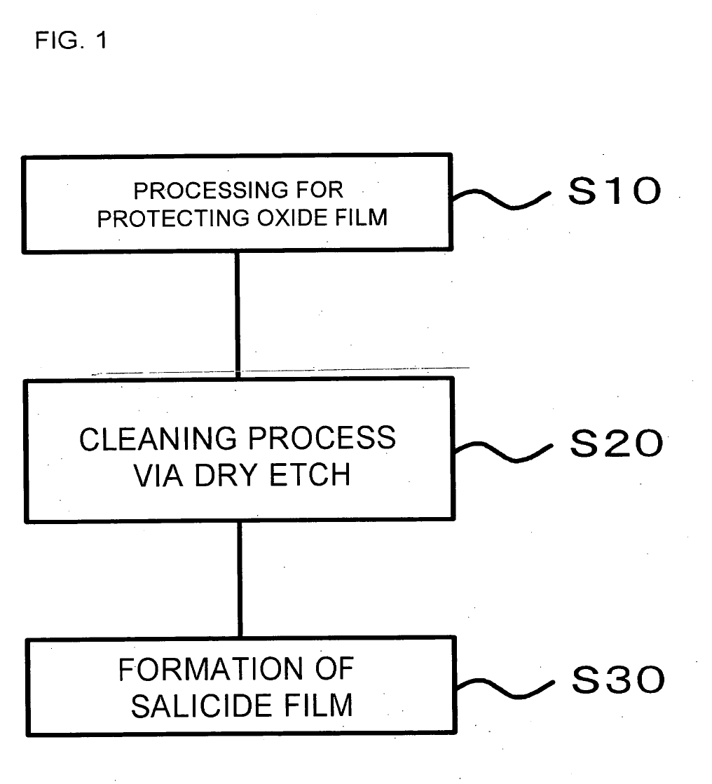

FIG. 1 is a flow chart, illustrating a procedure for manufacturing a semiconductor device in an embodiment of the present invention. In the present embodiment, prior to an operation for forming a salicide film (S30), an operation for providing a protection to an oxide film is conducted for the purpose of preventing a scattering of the oxide film onto a silicon substrate (S10). Then, an operation for cleaning the surface of the silicon substrate is conducted via a dry etch process (S20). Thereafter, a salicide film is formed (S30).

### (FIRST EMBODIMENT)

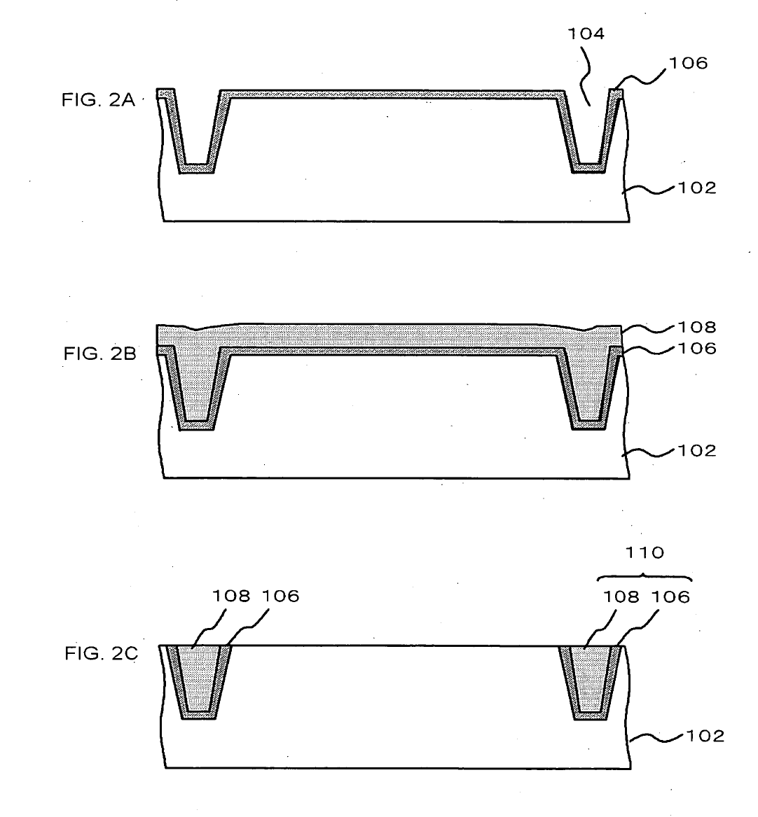

FIGS. 2A to 2C, FIGS. 3A to 3C and FIGS. 4A and 4B are cross-sectional views, illustrating a procedure for manufacturing a semiconductor device 100 according to the present embodiment.

First of all, a concave portion 104 is formed for providing a device isolation region in a silicon substrate 102. A dimension of the concave portion 104 is not particularly limited, but may be, for example, approximately 130 nm in width. Then, a silicon nitride film 106 is formed on the entire surface of the silicon substrate 102 via a chemical vapor deposition (CVD) process so as to cover the side walls of the concave portion 104 therewith (FIG. 2A). The film thickness of the silicon nitride film 106 is not particularly limited, but may be, for example, 5 nm to 20 nm. Subsequently, a silicon oxide film 108 is formed on the entire surface of the silicon substrate 102 via a CVD process so as to fill the concave portion 104 (FIG. 2B).

Thereafter, portions of the silicon oxide film 108 and the silicon nitride film 106 exposed outside of the concave portion 104 are removed via a chemical mechanical polishing (CMP) (FIG. 2C). With these operations, the device isolation region 110 is formed.

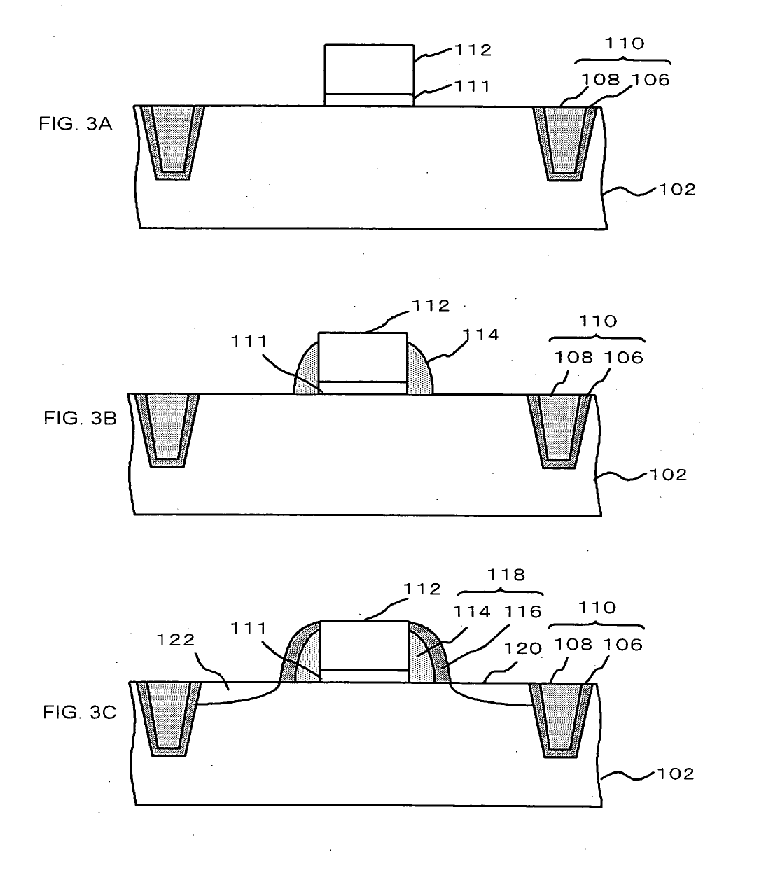

Then, a gate insulating film 111 and a gate electrode 112 are formed in a region on the silicon substrate 102 isolated by the device isolation region 110 via the following procedure (FIG. 3A). First, a silicon oxide film is formed on the surface of the silicon substrate 102 via a thermal processing. Then, a polysilicon film is formed on the silicon oxide film via a CVD process. Subsequently, the polysilicon film and the silicon oxide film are sequentially patterned to provide a geometry of a gate electrode thereto via a known lithographic technology. Having such procedure, the gate insulating film 111 composed of the silicon oxide film and the gate electrode 112 composed of the polysilicon film are formed.

Subsequently, a silicon oxide film is formed on the entire surface of the silicon substrate 102 via a CVD process. Then, the silicon oxide film is etched back to form a first side wall composed of the silicon oxide film 114 on the side surface of the gate insulating film 111 and the gate electrode 112 (FIG. 3B).

Thereafter, a silicon nitride film is formed on the entire surface of the silicon substrate 102 via a CVD process. Then, the silicon nitride film is etched back to form a second side wall, which is composed of the silicon nitride film 116 and covers the first side wall. The first side wall and the second side wall compose a side wall 118. Then, an ion implantation process is conducted through a mask of the gate insulating film 111, the gate electrode 112 and the side wall 118 to form a first diffusion layer 120 and a second diffusion layer 122 (FIG. 3C). The first diffusion layer 120 and the second diffusion layer 122 will form a source or a drain of a metal oxide semiconductor (MOS) transistor.

Alternatively, an ion implantation process may be conducted at relatively lower concentration through a mask of the gate insulating film 111 and the gate electrode 112 before forming the side wall 118, and then, another ion implantation process may be conducted at relatively higher concentration after the formation of the side wall 118 as described above, so that a MOS transistor of a lightly doped drain (LDD) structure can be formed. The process for manufacturing the MOS transistor described above is an exemplary implementation, and the MOS transistor may also be manufactured to have other various configurations by other various processes.

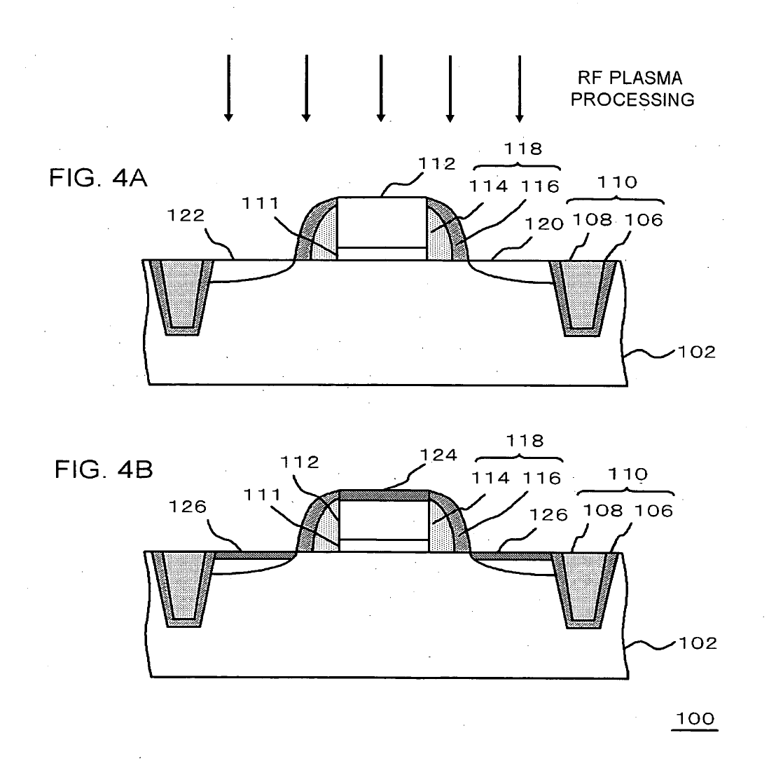

Subsequently, a dry etch process is performed on the entire surface of the silicon substrate 102 to remove the native oxide film and/or the contaminants formed on the surface of the silicon substrate 102 (FIG. 4A). Here, the dry etch process may utilize a radio frequency (RF) plasma processing that employs an inert gas such as nitrogen gas (N₂), argon gas (Ar) and the like. The RF plasma processing may be carried out in a conditions of, for example, vacuum: 1×10⁻⁶ torr to 1×10−8 torr; Ar gas flow rate: 5 to 40 sccm; RF: 200 to 800 W/HF: 50 to 200 W; and process time: 1 to 60 seconds. In addition, the available gas may also include a reducing gas such as hydrogen gas and the like. This operation can be conducted in the same deposition apparatus as employed in the above-mentioned operation. Since this can provide the removal of the native oxide film and the contaminants in the cleaning process without the need for unloading the silicon substrate 102 from the deposition apparatus, regeneration of the native oxide films after the cleaning process can be prevented, thereby achieving the manufacture of the semiconductor device having an improved reliability. Since the cleaning process in the present embodiment is carried out via the dry etching process instead of wet etching, the upper portion of the silicon oxide film 108 can be maintained to be substantially even. In addition, the upper portion of the silicon oxide film 108 is maintained to be substantially coplanar with the surface of the silicon substrate 102.

Thereafter, a metallic film is formed on the entire surface of the silicon substrate 102. In the present embodiment, the metallic film is composed of nickel. Then, a reaction of the metallic film with the silicon that is in contact with the metallic film may be induced by conducting a thermal processing to form a salicide film. Subsequently, unreacted portions of the metallic film is removed to form a salicide metal layer 124 on the gate electrode 112 and a salicide metal layer 126 on the first diffusion layer 120 and the second diffusion layer 122, respectively. Here, the salicide metal layer 124 and the salicide metal layer 126 are both nickel silicide (NiSi). As described above, the semiconductor device 100 according to the present embodiment is formed (FIG. 4B). Thereafter, an interlayer insulating film, which is in contact with the silicon oxide film 108 of the device isolation region 110, is formed on the entire surface of the silicon substrate 102 to have the MOS transistor embedded therein, though this is not shown in the drawings.

As described above, according to the method for manufacturing the semiconductor device in the present embodiment, sufficient cleaning can be achieved before forming the salicide film, thereby providing the manufacture of the semiconductor device having an improved reliability.

### (SECOND EMBODIMENT)

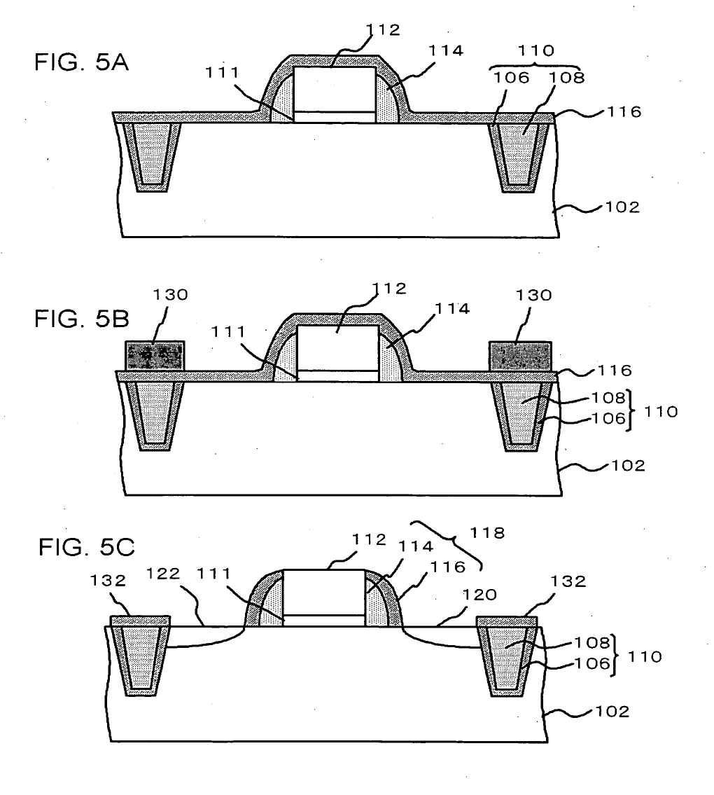

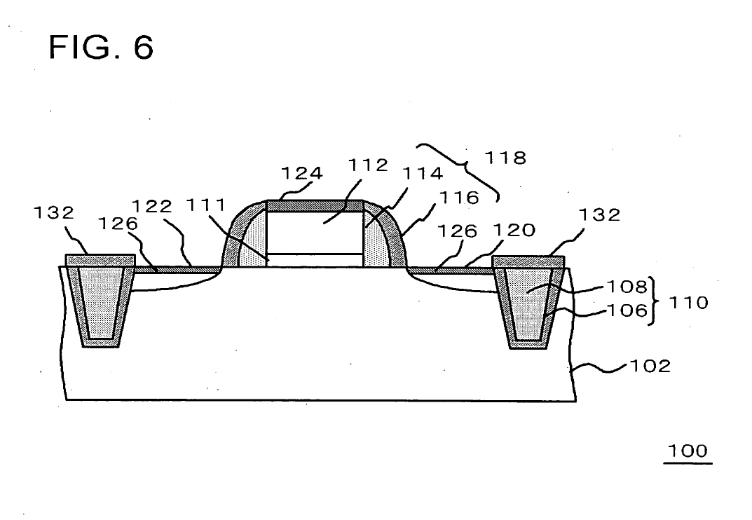

FIGS. 5A to 5C and FIG. 6 are cross-sectional views, illustrating a partial process for manufacturing the semiconductor device 100 in the present embodiment. First of all, a device isolation region 110 is formed on a silicon substrate 102 via a procedure same as that described in reference to FIGS. 2A to 2C in first embodiment. Then, a gate insulating film 111, a gate electrode 112 and a first side wall (silicon oxide film 114) are formed in a region isolated by the device isolation region 110 via a procedure same as that described in reference to FIGS. 3A and 3B in first embodiment. Then, a silicon nitride film 116 is formed on the entire surface of the silicon substrate 102 via a CVD process (FIG. 5A).

Subsequently, a resist layer 130 is selectively formed on the silicon nitride film 116. Thereafter, the resist layer 130 is patterned so as to mask only the region where the device isolation region 110 is formed (FIG. 5B).

Thereafter, the silicon nitride film 116 is etched by using a mask of the resist layer 130 (FIG. 5C). Subsequently, similarly as in the procedure described in first embodiment, a metallic film is formed on the entire surface of the silicon substrate 102 and then, the formed metallic film is patterned to form a salicide metal layer 124 on the gate electrode 112 and a salicide metal layer 126 on the first diffusion layer 120 and the second diffusion layer 122, respectively (FIG. 6). This allows obtaining the semiconductor device 100 having a cap layer 132 selectively formed on the upper portion of the device isolation region 110.

Since the device isolation region 110 includes the silicon nitride film 106 formed on the side wall of the concave portion 104 (not shown in Figs. SA to 5C) in the present embodiment, an allowance for the positioning can be ensured by the thickness of the silicon nitride film 106 when the cap layer 132 is formed on the device isolation region 110 through a mask of the resist layer 130, and thus the dimension of the cap layer 132 can be provided to be substantially the same as the surface area of the device isolation region 110.

In addition, as described above, the tensile stress created in the silicon substrate 102 viewing from the film formed on the silicon substrate 102 is increased by providing the silicon nitride film 106 on the side wall of the device isolation region 110, thereby promoting the formation of mono silicide. Therefore, even if the cap layer 132 is formed on the surface of the device isolation region 110, the tensile stress created in the silicon substrate 102 can be maintained to be a certain higher level, and thus, it is expected to reduce the formation of disilicide.

While the preferred embodiments and the exemplary implementations of the present invention have been described above in reference to the annexed figures, it should be understood that the disclosures above are presented for the purpose of illustrating the present invention, and various configurations other than the above described configurations can also be adopted.

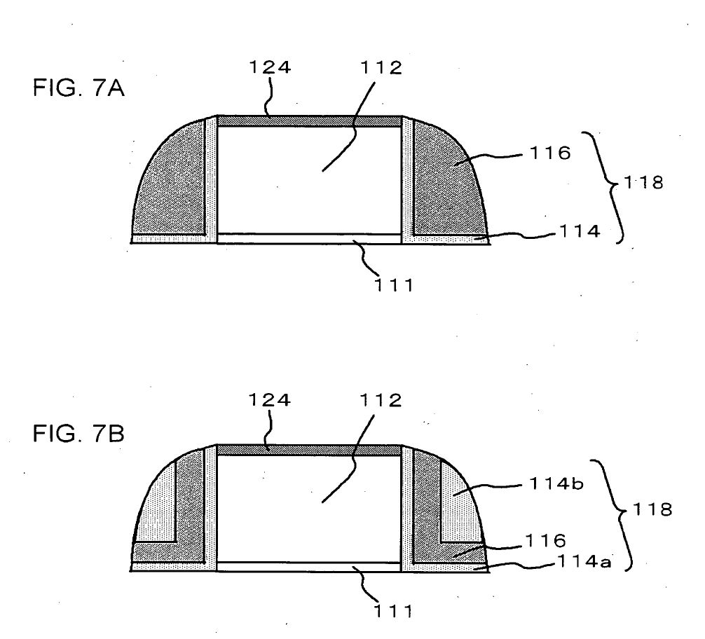

FIGS. 7A and 7B are cross-sectional views, illustrating other exemplary implementations of the side wall 118 of the semiconductor device 100 described in the above described embodiments.

As shown in FIG. 7A, the side wall 118 is composed of the silicon nitride film 116, and may be configured to have a thin film of the silicon oxide film 114 formed between the gate insulating film 111 and the silicon nitride film 116. The higher reliability of the transistor can be maintained by providing the silicon oxide film 114 between the gate insulating film 111 and the silicon nitride film 116 as described above to present a situation where the gate insulating film 111 is not in contact with the silicon nitride film 116.

Alternatively, as shown in FIG. 7B, the side wall 118 may be composed of the first silicon oxide film 114a, the silicon nitride film 116 and the second silicon oxide film 114b where the silicon nitride film 116 is formed between the first silicon oxide film 114a and the second silicon oxide film 114b. As such, even if the second silicon oxide film 114b is formed on the surface of the side wall 118, the scattering of the oxide can be prevented in the dry etch process by reducing a quantity of the existing silicon oxide film in vicinity of the silicon substrate 102, thereby allowing better cleaning process.

As described above, the side wall 118 may have various configurations.

It is apparent that the present invention is not limited to the above embodiment, and may be modified and changed without departing from the scope and spirit of the invention.

What is claimed is:

1. A method for manufacturing a semiconductor device, including:
forming a concave portion for forming a device isolation region in a silicon substrate;
filling said concave portion with an insulating film containing a first silicon nitride film to form the device isolation region, said first silicon nitride film being formed on a side wall of said concave portion;
forming a semiconductor element in a region isolated by said device isolation region on said silicon substrate, said semiconductor element including a gate electrode having a side wall formed at a side surface thereof;
etching the entire surface of said silicon substrate by a dry etching process; and
forming a salicide film on said silicon substrate after said dry etching process.

2. The method according to claim 1,
wherein said forming the semiconductor element includes:
forming said gate electrode; and
forming said side wall at the side surface of said gate electrode, said side wall including a second silicon nitride film on at least a portion of the surface, and
wherein, in said forming the salicide film, the salicide film is formed on said gate electrode.

3. The method according to claim 1, wherein said forming the device isolation region includes:
forming said first silicon nitride film on the entire surface of said silicon substrate to cover the side wall of said concave portion;
forming a silicon oxide film on the entire surface of said silicon substrate to fill said concave portion; and
removing portions of said first silicon nitride film and said silicon oxide film that are exposed to the outside of said concave portion.

4. The method according to claim 2, wherein said forming the device isolation region includes:
forming said first silicon nitride film on the entire surface of said silicon substrate to cover the side wall of said concave portion;
forming a silicon oxide film on the entire surface of said silicon substrate to fill said concave portion; and
removing portions of said first silicon nitride film and said silicon oxide film that are exposed to the outside of said concave portion.

5. The method according to claims 1, further comprising forming a third silicon nitride film on the surface of said device isolation region to cover the device isolation region, before said dry etching process.

6. The method according to claims 2, further comprising forming a third silicon nitride film on the surface of said device isolation region to cover the device isolation region, before said dry etching process.

7. The method according to claims 1, wherein said salicide film is composed of nickel silicide.

8. A semiconductor device, comprising:
a silicon substrate;
a device isolation region filled with an insulating film, said insulating film including a first silicon nitride film formed at a side wall of a concave portion that is formed in said silicon substrate;
a semiconductor element including a gate electrode that has a side wall formed at a side surface thereof, said semiconductor element being formed in a region on said silicon substrate that is isolated by said device isolation region; and
a salicide film formed on said silicon substrate,
wherein an upper portion of said insulating film is formed to be substantially even.

9. The semiconductor device according to claim 8, wherein said semiconductor element comprises:
a gate electrode;
a side wall formed at a side wall of said gate electrode, said side wall including a second silicon nitride film in at least a portion of the surface; and
a salicide film formed on said gate electrode.

10. The semiconductor device according to claim 8, wherein said device isolation region includes:
said first silicon nitride film formed at the side wall of said concave portion; and
a silicon oxide film formed on said first silicon nitride film, said silicon oxide film filling said concave portion.

11. The semiconductor device according to claim 9, wherein said device isolation region includes:
said first silicon nitride film formed at the side wall of said concave portion; and
a silicon oxide film formed on said first silicon nitride film, said silicon oxide film filling said concave portion.

12. The semiconductor device according to claim 8, further comprising a third silicon nitride film formed on the surface of said device isolation region to cover the device isolation region.

13. The semiconductor device according to claim 9, further comprising a third silicon nitride film formed on the surface of said device isolation region to cover the device isolation region.

14. The semiconductor device according to claim 8, wherein said salicide film is composed of nickel silicide.

15. The semiconductor device according to claim 9, wherein said salicide film is composed of nickel silicide.

16. The semiconductor device according to claim 8, wherein said salicide film is formed on the surface of said silicon substrate, on which the dry etching process is conducted.

17. The semiconductor device according to claim 9, wherein said salicide film is formed on the surface of said silicon substrate, on which the dry etching process is conducted.
